(19) United States
(12) Patent Application Publication
(10) Pub. No.: US 2016/0079073 A1
(43) Pub. Date: Mar. 17, 2016

(54) PLASMA PROCESSING METHOD

(71) Applicant: Hitachi High-Technologies Corporation, Tokyo (JP)

(72) Inventors: Miyako MATSUI, Tokyo (JP); Kenetsu YOKOGAWA, Tokyo (JP); Tadamitsu KANEKIYO, Tokyo (JP); Tetsuo ONO, Tokyo (JP); Kazunori SHINODA, Tokyo (JP)

(73) Assignee: HITACHI HIGH-TECHNOLOGIES CORPORATION

(21) Appl. No.: 14/626,909

(22) Filed: Feb. 19, 2015

(30) Foreign Application Priority Data
Sep. 11, 2014 (JP) 2014-184745

(51) Int. Cl. H01L 21/3065

(52) U.S. Cl. CPC H01L 21/3065

(57) ABSTRACT

A plasma processing method includes: a first step of introducing a gas having reactivity with a film to be processed disposed in advance on a top surface of a wafer into a processing chamber to form an adhesion layer on the film; a second step of expelling a part of the gas remaining in the processing chamber while supply of the gas having reactivity is stopped; a third step of introducing a rare gas into the processing chamber to form a plasma and desorbing reaction products of the adhesion layer and the film to be processed using particles and vacuum ultraviolet light in the plasma; and a fourth step of expelling the reaction products while the plasma is not formed.

### BACKGROUND OF THE INVENTION

The present invention relates to a plasma processing method of performing etching processing of a substrate-like sample such as a semiconductor wafer mounted in a processing chamber within a vacuum container.

With miniaturization of functional element products such as semiconductor devices, thinning of gate insulation layers, interlaminar layers, and the like which form a device has been advanced together with increase in the aspect ratios. Further, limitations in the miniaturization of semiconductor devices are imminent and development of three-dimensional devices is accelerated.

In the process of machining of a gate of a device having an Fin-FET (Fin-based Field Effect Transistor) structure, for example, as one of the three-dimensional devices, an etching technique is required in which the amount of over-etching of a base having a different height of a substrate portion from the Fin part is controlled at an atomic-layer level with high selectivity. Furthermore, along with the thinning of the interlaminar layer such as a gate insulation layer and a spacer layer, a processing technique of etching uniformly in a plane of a semiconductor wafer at an atomic-layer level with high selectivity with respect to material of a layer other than a layer of material to be etched is required.

Moreover, a technique of isotropic etching of material to be etched underlain by a mask material with high accuracy at an atomic-layer level has become important along with advancement of three-dimensional device structures. Further, when a minute pattern having a high aspect ratio is manufactured, the pattern is apt to collapse due to the surface tension at the time that rinse liquid is dried in a process of washing and/or machining as being WET using liquid chemicals.

For example, when a pattern of a high aspect ratio of Si is used, it is known that a limit value of a pattern spacing at which collapse begins with a narrow pattern spacing is increased in proportion to a square of an aspect ratio. Accordingly, it is supposed that there arises in the future a large problem having a risk that a pattern collapses in a WET washing or a machining process of a pattern surface along with progress of miniaturization and increasing aspect ratios.

Regarding such problems, there is developed in recent years a technique of etching finer thickness as compared with the prior art by desorbing gas and/or radicals after their adhesion. In such an adhesion and desorption technique, first, etchant such as process gas, radicals, or vapor is supplied into a processing chamber in which a wafer having film structures to be processed being disposed on their surfaces is placed so that they are caused to adhere onto the surfaces of the layers to be etched (Step 1). Next, after the etchant is expelled (Step 2), the wafer is irradiated with low-energy ions or electrons or heated so as to desorb reaction products formed by reaction between a film of the etchant adhering onto the surface and the surface of the film to be etched (Step 3). Thereafter, the reaction products are expelled out of the processing chamber (Step 4).

Moreover, the process of a pair of adhesion and desorption as described above is defined as one cycle and this cycle is repeatedly performed by the number of times requested, so that the etching processing is performed to the layer to be processed. According to such the technique, there does not arise a problem of the collapse of patterns in the processings as compared with the prior-art technique using the liquid chemicals. Further, there is an advantageous effect that the amount of etching in one cycle of adhesion and desorption is small and steady, and the total amount of etching can be controlled by the number of times of repeated cycles.

As an example of such the technique, there is known as described in, for example, Journal of Vacuum Science and Technology B, Vol. 14, No. 6, 3702 (1996) that, after a substrate to be etched is exposed to a reactive gas so that a reactive gas etchant is caused to adhere onto the surface of a film to be etched, the substrate to be etched is irradiated with ions, electrons, or high-speed neutral particles produced by an inert gas plasma and the adhering reactive gas and the film to be etched are caused to react to desorb from the surface, and they are exhausted from the inside of a chamber. Furthermore, as disclosed in JP-A-2014-007432, there is known a technique that, after a substrate to be processed is disposed in a chamber, a reactive gas is supplied into the chamber to form a plasma, so that ionized reaction agents are caused to adhere to the substrate surface, and thereafter a potential difference between the plasma and the substrate is increased to adjust ion energies so that the substrate is etched by the adhering reaction agents.

In the etching processings according to the above prior-art techniques, etchant is supplied inside a chamber by supplying a reactive gas into a chamber in which a wafer that is a substrate-like sample such as a semiconductor wafer is disposed and forming reactive species with a plasma formed using it, supplying vapor of a reactive gas, or the like and the etchant is caused to adhere to the surface of a film to be processed having a film structure on the top surface of the wafer (Step 1). Next, the gas in the chamber is exhausted together with remaining etchant so that the film structure is not adversely affected by the reactive species of the reactive gas which did not adhere (Step 2). Thereafter, the surface of the film to which the etchant adheres is irradiated with ions having relatively low energies so that reaction products formed by letting the etchant and material of the film to be processed react are vaporized (desorbed) (Step 3). Further, the inside of the chamber is exhausted lest the particles of the desorbing reaction products should attach again in the chamber and adversely affect subsequent processings of the wafer (Step 4).

Furthermore, as an example of heating a substrate to be etched and letting reaction products desorb instead of the process of irradiating the substrate to be etched with charged particles or neutral particles by plasma, there has been known, for example, as disclosed in JP-A-2006-523379, that the temperature of a substrate holder on which a substrate is placed is first set to be 10° C. or more and 50° C. or less to cause etchant made of an HF gas and an NH₃ gas to adhere onto an SiO₂ film on a surface of a substrate, and afterwards the substrate is heated to be 100° C. or more and 200° C. or less in a heat treatment chamber so as to desorb reaction products. Moreover, an etching processing in which a reactive gas is caused to adhere onto a material to be etched at a first temperature and thereafter reaction products on the surface of a wafer is caused to desorb by heating the surface of the wafer to a second temperature is disclosed in JP-A-2005-244244 and JP-A-2003-347278.

### SUMMARY OF THE INVENTION

In the prior-art techniques described above, the following aspects are not considered sufficiently and problems arise accordingly.

That is, there is a problem that, when a dense pattern and holes or a groove pattern having high aspect ratios are processed, the number of ions induced by plasma to collide with the upper part of the patterns and the upper part of side walls of the patterns is relatively high and energies are supplied to the parts so that etching advances whereas ions reaching the lower part and the bottom part of the side walls of the patterns do not exist or are relatively small in number and, therefore, etching does not advance or the degree of progress is small; then, the etching rates are greatly different in the upper and lower parts of the patterns and the desired dimensions cannot be obtained after an etching processing of a prescribed time. Further, there is a problem that, when patterns of two or more kinds having different densities are formed on the surface of the same wafer, the number of ions with which the bottom part of a pattern of a higher density is irradiated per unit area of the wafer is smaller than that of ions with which the bottom part of a pattern of a lower density is irradiated and, accordingly, the etching rate of the pattern having a higher density is lowered so that the dimensions of the patterns after machining are widely scattered in the plane of the wafer.

Moreover, even when material to be etched is etched isotropically in a pattern having dimensions (for example, a spacing between adjacent grooves) greater in the upper part than in the bottom part, ions produced in the plasma enter in a direction vertical to the wafer surface with a certain angular distribution. Therefore, there is a problem that apart which is shaded when such a pattern is irradiated with ions cannot be etched.

Further, in the prior art, underlying material on which a film of material to be etched is disposed is sometimes damaged by the impact of ion irradiation. When the damage by the impact of ions is excessively large, the performance of the devices which are miniaturized and highly integrated today is lowered. Moreover, when roughness by damage and/or unevenness is formed on the surface of the material to be etched by such ion impact, there is a problem that the thickness of an adhesion film formed in the processing cycles of adhesion and desorption performed thereafter is increased and the etching rate is increased with the number of such cycles performed to reduce the etching accuracy.

Furthermore, in the prior art described above, there is a problem that one etching cycle requires very long time. Particularly, there is a problem that the time required to expel out of the chamber gases and particles with which there is a risk that the processings in Steps 2 and 4 are adversely affected becomes longer and the throughput of the processings is deteriorated. Also, the techniques of JP-A-2005-244244 and JP-A-2003-347278 that the wafer is heated to raise its temperature and adhering reactive species and the surface of the material to be etched are caused to react with each other have a problem that, when proper temperatures in a Step of letting the reactive species adhere and a Step of causing them to desorb are different, it is necessary to change the temperature of the wafer in each Step and the throughput is deteriorated when the time for changing the temperature of the wafer is long.

For example, JP-A-2006-523379 discloses a system provided with a chemical processing chamber in which reactive species are caused to adhere to the upper surface of a substrate and a heat treatment chamber in which the substrate is heated to let the reactive species desorb from the substrate. NH₃ and/or HF are used as reactive gases for supplying the adhering reactive species.

When both of the adhesion and the desorption are performed on a single wafer stage in a single processing chamber, it is necessary to change the temperature of the wafer stage between two temperatures which are a room temperature suitable for the adhesion and a prescribed temperature of 100° C. or more and 200° C. or less suitable for the desorption (for example, 120° C.) as many times as the number of cycles of the adhesion and the desorption, and both of the temperatures for the wafer and the stage must be adjusted, so that the time required to adjust the temperatures becomes longer and the throughput of the processings is remarkably deteriorated. Further, when the reactive gases remain on a wall or the like of the processing chamber even after the process of letting the reactive species adhere onto the substrate using the reactive gases and the substrate is heated in the same processing chamber, it reacts with the film to be processed on the upper surface of the substrate, so that profiles after machining become different from desired ones. Accordingly, in JP-A-2006-523379 two processing chambers are provided for performing the two processing operations separately.

In this prior art, the temperature of the substrate in the chemical processing chamber is adjusted to the range of about 10° C. to 30° C., or about 25° C. to 30° C. The reactive species formed from gases of HF and NH₃ supplied to the chemical processing chamber as the reactive gases while the substrate is set to such a temperature adhere onto the upper surface of the substrate. Such reactive species chemically react with the film of material to which the reactive species adhere and the reaction products, for example, (NH₄)₂SiF₆ are produced.

Since reactive gases containing the reactive species which did not adhere remain in the chemical processing chamber, an inert gas such as a rare gas is introduced into the processing chamber while exhausting the reactive gases by a vacuum pump and gases in the chamber are replaced so that action on the substrate by the reactive gases is not advanced. Thereafter, the substrate is transferred to a thermal processing chamber and is mounted on a substrate holder for heating.

The substrate is adjusted to a temperature in the range of about 100° C. to 200° C., so that the reaction products are desorbed from the surface of the substrate. The reaction products desorbed from the surface are exhausted from the chamber by a vacuum pump.

In this prior art, letting the processes of such adhesion, exhaust, desorption, and exhaust be one cycle, this cycle is repeated to perform etching processing. However, it takes long time to perform the exhaust process after the adhesion and desorption processes and, since different temperatures of the substrate must be further realized in the adhesion and the desorption, it requires long time to change the temperature before the beginning of the processes. Moreover, since time for moving the substrate between two processing chambers is required, there is a problem that the throughput of the processings is deteriorated.

As described above, in the prior art, as being affected by densities and shapes of the mask patterns of the film structure to be processed, there arises a problem that the dimensions after machining obtained as a result of processing vary remarkably and the accuracy of the etching processing is deteriorated. Further, there is a problem that it takes long time to change the temperature of the substrate and the processing throughput is deteriorated.

Moreover, there is a possibility that material and/or pattern may be damaged by raising and lowering the temperature of the substrate many times in the process of fabricating a semiconductor device which is miniaturized and highly integrated these days or the performance of the device after machining is reduced. A problem that the yield of processing of the substrate may be deteriorated by the above problem is not considered in the prior art described above.

It is an object of the present invention to provide a plasma processing method in which the yield is improved.

The Inventors have discovered that variations in the processing accuracy in accordance with densities and shapes of patterns are suppressed and deterioration of the throughput and the yield is suppressed by producing a plasma using rare gases in a processing chamber after reactive species obtained from reactive gases are caused to adhere to the surface of material to be etched on a substrate disposed in the processing chamber and causing reaction products to desorb by irradiating the surface of the material to be etched to which the reactive species are caused to adhere with vacuum ultraviolet (VUV) light and metastable atoms formed thereby.

More concretely, in order to achieve the above object, the plasma processing method of the present invention includes a first step of disposing a wafer to be processed in a processing chamber depressurized in a vacuum container and introducing into the processing chamber a gas having reactivity with a film to be processed disposed in advance on a top surface of the wafer to form an adhesion layer on the film; a second step of expelling a part of the gas having reactivity which remains in the processing chamber while supply of the gas having reactivity is stopped; a third step of introducing a rare gas into the processing chamber to form a plasma in the processing chamber and desorbing reaction products of the adhesion layer and the film to be processed from the wafer using particles in the plasma and vacuum ultraviolet light generated from the plasma; and a fourth step of expelling the reaction products from the processing chamber while the plasma is not formed.

According to the method of the present invention, material to be etched is irradiated with the VUV light and metastable atoms and energy for the adhesion film with the material to be etched to react can be given efficiently, so that the reaction products can be desorbed from the surface of the material to be etched. At this time, even when the pattern on the wafer to be etched has difference in density, there is a pattern having a high aspect ratio, or the material to be etched is positioned toward the inside as compared with the upper surface of the pattern, complicated patterns can be etched with high throughput at high accuracy regardless of their shapes. Further, since the wafer temperature is not required to be raised to high temperature in the desorption process of the reaction products and variations of the wafer temperature in the adhesion process and the desorption process become small, the etching processing time is shortened and the throughput of the wafer processing is improved. Moreover, since irradiation with ions or heating of the wafer to high temperature is not necessary, damages by the etching processing can be eliminated and the device characteristics can be improved.

Other objects, features, and advantages of the invention will become apparent from the following description of the embodiments of the invention taken in conjunction with the accompanying drawings.

### BRIEF DESCRIPTION OF THE DRAWINGS

FIGS. 1A to 1C show longitudinal sectional views schematically illustrating examples of patterns of film structures disposed on the surface of a sample to be processed in embodiments of the present invention;

FIG. 2 shows a flow chart indicating a flow of processing operation of a plasma processing apparatus according to an embodiment of the present invention;

FIG. 3 shows longitudinal sectional views schematically illustrating change in progress of the processing of the film structure of the sample subjected to the processing according to the embodiment shown in FIG. 2;

FIG. 4 shows a longitudinal sectional view schematically illustrating the configuration of the plasma processing apparatus according to the embodiment of the present invention;

FIG. 5 shows a timing chart exhibiting a flow of processing operation for removing a film to be processed in the plasma processing apparatus according to the embodiment shown in FIG. 4;

FIG. 6 shows a longitudinal sectional view schematically illustrating the configuration of a variation of the plasma processing apparatus according to the embodiment shown in FIG. 4; and

FIG. 7 shows a timing chart exhibiting a flow of processing operation for removing a film to be processed in the plasma processing apparatus according to the embodiment shown in FIG. 6.

### DESCRIPTION OF THE EMBODIMENTS

Embodiments of the present invention are now described in detail with reference to the accompanying drawings. In all the drawings for explaining the embodiments, elements having the same function are given the same reference numerals and repeated description thereof is omitted.

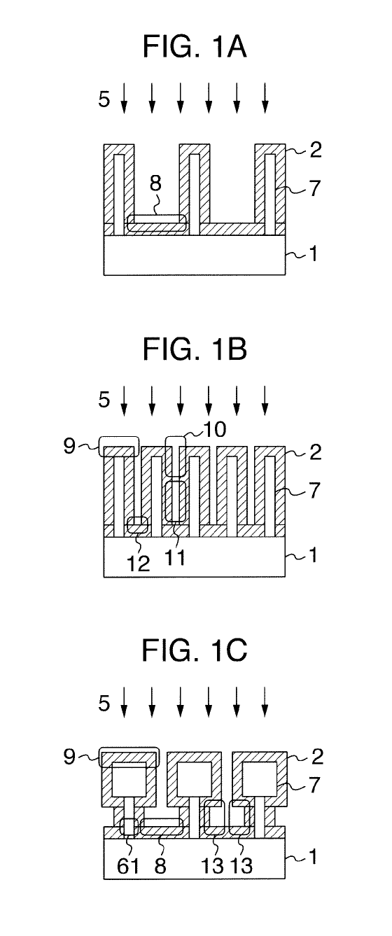

First, FIGS. 1A to 1C schematically illustrate patterns of film structures disposed on the surface of a sample to be processed according to the present invention. As shown in FIG. 1A, in case where the density of a pattern 7 is low and the aspect ratio is low, ions 5 from a plasma reach a bottom 8 of the pattern even at low energies in the Step 3 in the prior art described above and, accordingly, etchant and a surface of material 2 to be processed react with each other to form reaction products with ion energies possessed by them and the pattern 7 can be etched to desired dimensions along a mask by letting them desorb from the surface of the bottom 8 of the pattern.

However, when a dense pattern or a hole or groove pattern having a high aspect ratio as shown in FIG. 1B is processed, the number of ions 5 colliding with an upper part 9 of the pattern 7 and an upper part 10 of a side wall of the pattern is relatively large and energy is supplied to the parts so that etching is advanced, while ions 5 reaching a lower part 11 or a bottom 12 of the side wall of the pattern do not exist or are relatively small in number and the etching is not advanced or a degree of advance is small, therefore, the etching rate is remarkably different in the upper and lower parts of the pattern 7, so that there is a problem that desired dimensions cannot be obtained after the etching processing of a prescribed time. Further, when patterns of two or more kinds having different densities are formed on the surface of a single wafer, ions with which the bottom 12 of the pattern having high density is irradiated are smaller in number per unit area of the wafer than ions with which the bottom 8 of the pattern having low density is irradiated and, accordingly, the etching rate of the pattern having high density is reduced and there is a problem that the dimensions of the patterns after machining vary widely in the plane of the wafer.

Furthermore, as shown in FIG. 1C, when the material 2 to be processed is isotropically etched in a pattern where the upper part 9 of the pattern is larger than the bottom 61 of the pattern, ions generated in the plasma enter the surface of the wafer 1 vertically with a certain angular distribution. Accordingly, there is a problem that parts 13, which are shaded when the pattern 7 is irradiated with ions 5, cannot be etched.

The Inventors have discovered that variations in the processing accuracy in accordance with densities and shapes of patterns are suppressed and deterioration of the throughput and the yield are suppressed by producing a plasma using rare gases in a processing chamber after reactive species obtained from reactive gases are caused to adhere onto the surface of material to be etched on a substrate disposed in the processing chamber and causing reaction products to desorb by irradiating the surface of the material to be etched onto which the reactive species adhere with VUV light and metastable atoms formed thereby so that the problems described above are solved. The invention represented in the present embodiment is thought up based on the above discovery.

### Embodiment

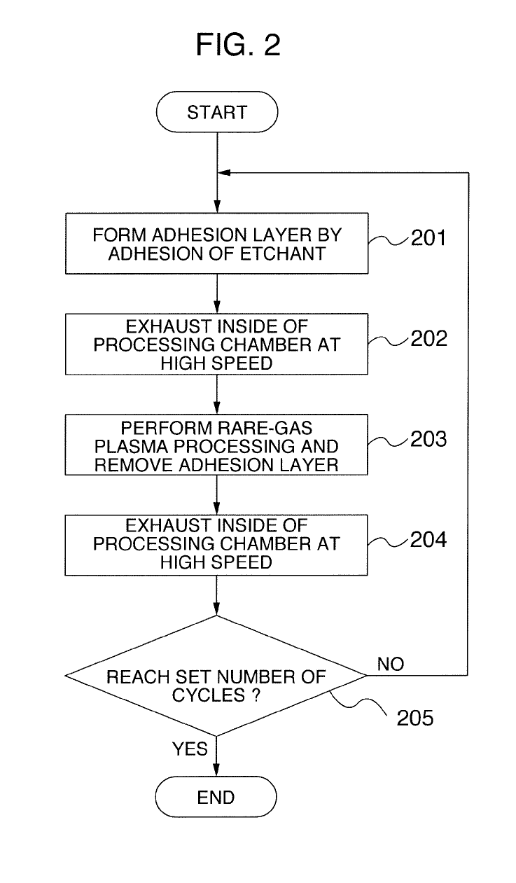

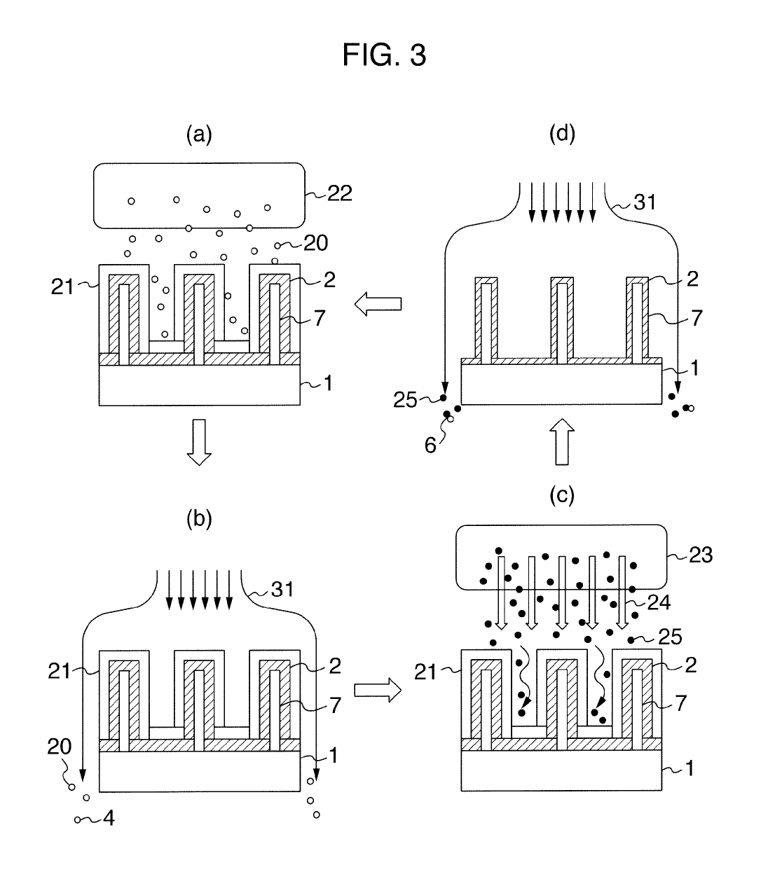

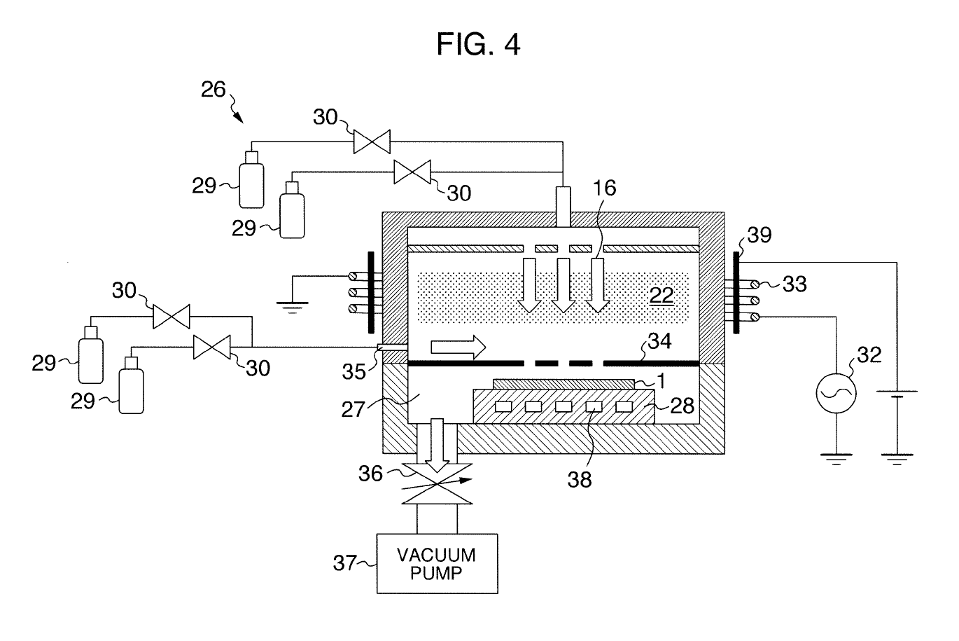

An embodiment of the present invention is now described with reference to FIGS. 2 to 4. FIG. 2 shows a flow chart indicating a flow of processing operation of a plasma processing apparatus according to the embodiment of the present invention. FIG. 3 shows longitudinal sectional views schematically illustrating change in progress of the processing of the film structure of a sample subjected to the processing according to the embodiment shown in FIG. 2. FIG. 4 shows a longitudinal sectional view schematically illustrating a configuration of the plasma processing apparatus according to the embodiment of the present invention.

FIG. 4 shows an example of the configuration of the plasma processing apparatus, particularly a plasma processing apparatus, which performs the plasma processing method according to the present embodiment. In this example, a plasma processing apparatus 26 includes: a processing chamber 27 which is disposed in a vacuum container, provides room where a plasma 22 is formed, and is reduced in pressure; a wafer stage 28 disposed in a lower part in the processing chamber 27; and gas supply measures including gas cylinders 29 which are coupled to the vacuum container and constitute gas sources of process gases and rare gases, gas pipes which are coupled to them and constitute gas supply paths, and valves 30 which are disposed in the paths and regulate open/close and rates of gas flows. Further, an exhaust device is disposed below the vacuum container and coupled to the vacuum container, which communicates with the processing chamber 27 through an exhaust exit disposed under a top surface of the wafer stage 28 and includes a variable conductance valve 36 and a vacuum pump 37 so that the processing chamber 27 is evacuated.

On the outer peripheral side of a cylindrical part of the vacuum container which surrounds the periphery of the processing chamber 27 having a cylindrical shape, there are disposed a spiral coil 33 which is wound to surround side walls of the processing chamber 27 and the vacuum container, and a shield electrode 39 made of a conductor which is disposed between the coil 33 and the side wall of the vacuum container to surround the side wall of the vacuum container and rendered to be at a prescribed potential. One end of the coil 33 is electrically grounded and the other end thereof is electrically connected to a radio-frequency (RF) power supply 32 which supplies RF power having a prescribed frequency to the coil 33. Further, in the embodiment, the shield electrode acts as a Faraday shield and is set to the ground potential.

In the embodiment, the gas supply measures include plural gas sources and supply paths of different kinds of gases, which are coupled to the vacuum container; the gases supplied respectively from the gas cylinders 29 into the supply paths are adjusted in their flow rates by the valves 30 and supplied into the processing chamber 27 within the vacuum container. In the embodiment, there are provided: a path coupled to the vacuum container in an upper part of the processing chamber 27 so as to introduce a gas into the processing chamber 27 downward through a plurality of through-holes in the center part of a shower plate which constitutes a ceiling surface of the processing chamber 27 disposed above a mounting surface, which is the top surface of the wafer stage 28 and the wafer 1 is mounted on; and a path coupled to a plurality of other different gas cylinders 29 and connected to the side wall of the vacuum container so as to introduce a gas in the lateral direction (in the direction to the right from the left of the wafer stage 28 in the figure) from a route communicating with a gas supply inlet 33 disposed in the cylindrical inner wall of the processing chamber 27 above the top surface of the wafer stage 28.

In the embodiment, reactive gases 16 containing reactive species adhering onto a film 2 to be processed or rare gases 31 for generating vacuum ultraviolet (VUV) light 24 and metastable atoms 25 can be introduced into the processing chamber 27 with the gas supply measures having these paths. A process gas containing the reactive gases 16 and the rare gases 31 is supplied into the processing chamber 27 downward through the gas introduction holes in the center part of the circular shower plate above the processing chamber 27. Instead of the shower plate, a doughnut-shaped introduction pipe, which is disposed inside the processing chamber 27 above the top surface of the wafer stage 28, communicated with the gas supply paths, and have a plurality of through-holes for introduction of gases, may be also used.

Atoms or molecules of the reactive gases 16 or the rare gases 31 introduced into the processing chamber 27 are excited by an electric field formed in the processing chamber 27 by RF power supplied from an RF power supply 32 to the spiral coil 33, so that the plasma 22 is formed. The atoms or molecules are activated at this time to produce radicals 20, and particles of the radicals 20 reach a surface of the wafer 1 below, so that they adhere onto a surface of the film 2 to be processed having a film structure formed in advance to con figure a layer and form an adhesion layer 21. The frequency of the RF power supply 32 can be properly selected from a range of 400 kHz to 40 MHz; in the embodiment 13.56 MHz is used.

Not only the radicals 20 but also charged particles such as ions and electrons are contained in the plasma 22. When a lot of ions reach the film 2 to be processed on the top surface of the wafer 1, the adhesion layer 21 is prevented from growing to a desired thickness. In order to suppress it, a filter 34 may be disposed between room which is above the top surface of the wafer 1 in the processing chamber 27 and where the plasma 22 is formed and the wafer 1. The filter 34 in this embodiment serves to let the radicals 20 permeate while suppressing the charged particles in the processing chamber 27 from falling toward the wafer 1; it is made of a plate-like member constructed with dielectric material such as quartz with a plurality of through-holes, which the radicals pass through, being arranged above the central part of the wafer 1.

Alternatively, the reactive gas 16 introduced into the processing chamber 27 can be caused to adhere onto the film 2 to be processed on the top surface of the wafer 1 directly rather than causing the radicals 20 formed by producing the plasma 22 with the reactive gas 16 to adhere to the film 2 to be processed. In this case, the gas supply inlet 35 of the reactive gas 16 may be disposed with respect to height in a position between the room in which the plasma 22 would be produced by using the reactive gas introduced from the gas introduction holes in the center part of the shower plate above the processing chamber 27 into the processing chamber 27 and the top surface of the wafer 1 so that the reactive gas 16 may be supplied from the gas supply inlet 35 via the through-holes of the filter 34 directly to the top surface of the wafer 1. In the example of FIG. 4, the gas supply inlet 35 is positioned above the filter 34.

The rare gases 31 introduced into the processing chamber 27 through the gas introduction holes in the shower plate communicating with the gas supply measures are excited by the RF power supplied from the RF power supply 32 to the coil 33 to produce rare-gas plasma 23, and the rare-gas plasma 23 generates VUV light 24 and metastable atoms 25 in the processing chamber 27.

The metastable atoms 25 diffuse in the processing chamber 27 and reach the surface of the wafer 1. Since the metastable atoms 25 have no directivity, they can reach even the bottom 12 of a pattern having a high aspect ratio and provide reaction energy thereto. Part of the VUV light 24 generated from the rare-gas plasma 23 can reach the surface of the wafer and provide reaction energy thereto.

Moreover, the pressure in the processing chamber 27 can be maintained to be constant with the variable conductance valve 36 and the vacuum pump 37 connected to the processing chamber 27 in the state that the process gas of a desired flow rate is supplied to flow. Further, a heating/cooling mechanism can also be provided in the wafer stage 28 to adopt a configuration in which the temperature of the wafer can, for example, be controlled to be 0 to 50° C. In the present embodiment, a coolant flow passage 38 is provided in a cylindrical metallic member inside the wafer stage 28, and the temperature of the wafer 1 can be cooled down to 30° C. or less by dissipating heat which the coolant flowing inside receives from the metallic member to a heat exchanger (not shown) disposed outside the wafer stage 28.

In the present embodiment, the processing of etching the film 2 to be processed without scraping off the pattern 7 of underlying poly-silicon is described with reference to FIGS. 2 to 5 for the case where such a plasma processing apparatus 26 performs the etching processing of the wafer 1 mounted on the wafer stage 28 in the processing chamber 27 and where a thin film of Si₃N₄ which is the film 2 to be processed of the material to be etched is formed on the surface on which the pattern 7 of poly-silicon in a form of grooves is formed in the top surface of the wafer 1 made of silicon which is the substrate-like sample to be processed.

First, as shown in Part (a) of FIG. 3, the etchant such as the reactive gases having reactivity with Si₃N₄ which is the material constituting the film 2 to be processed and the radicals 20, or vapor is supplied into the processing chamber inside which the wafer 1 on which a pattern containing the film 2 to be processed is formed is disposed so that the adhesion layer 21 is formed on the surface of the film 2 to be processed (Step 201 of FIG. 2). In the present embodiment, a CHF₃ gas is supplied into the processing chamber, the radicals 20 generated from the plasma 22 formed using it and the like are caused to adhere onto the surfaces of the layer 2 to be processed and the pattern 7, and the adhesion layer 21 is formed. The etchant such as the reactive gas, the radicals 20, and vapor can form the adhesion layer 21 isotropically even when the pattern 7 to be etched is uneven.

Usually, only part of the etchant forms the adhesion layer 21 and the rest would remain in the processing chamber 27 if no measures were taken. Hence, as shown in Part (b) of FIG. 3, the variable conductance valve 36 is fully opened to maximize the conductance and the reactive gases 4 and the radicals 20 remaining over the top surface of the wafer are exhausted from the processing chamber 27 in as a short time as possible (Step 202 of FIG. 2) lest the film 2 to be processed should be subjected to unnecessary etching by such the remaining etchant such as the reactive gases 4 and the radicals 20.

At this time, a gas having material or composition of a different kind from the reactive gases 4 may be introduced to replace the remaining gas with it. In the present embodiment, only rare gases are supplied into the processing chamber 27 in Step 202 and in the subsequent Step 203.

Next, as shown in Part (c) of FIG. 3, a rare-gas plasma 23 is produced in the processing chamber 27 with the rare gases supplied into the processing chamber 27. The surface of the film 2 to be processed is irradiated with the VUV light 24 generated thereby (Step 203 of FIG. 2).

Furthermore, the metastable atoms 25 formed in the rare-gas plasma 23 reach the surface of the film 2 to be processed on the wafer 1 disposed below and cause the adhesion layer 21 and the surface of the film 2 to be processed to react with each other to thereby form reaction products 6.

The temperature of the wafer 1 is adjusted within a range of values suitable for vaporization of such the reaction products 6, so that the reaction products 6 are desorbed (separated) over the wafer 1. At this time, since the VUV light 24 can provide energy to the surface of the pattern 7 efficiently, the adhesion layer 21 and the surface of the film 2 to be processed are caused to react with each other and the reaction products 6 can be desorbed without raising the temperature of the entire wafer.

Moreover, since the metastable atoms 25 have a long life and can come toward the pattern 7 from the plasma 23 above with no directivity, even when the wafer 1 is extremely uneven or the upper part 9 of the pattern is wider than the lower part as shown in FIG. 1C, they can reach the surface of the film 2 to be processed in the lower part or the bottom 8 and can give thereto energy for causing the adhesion layer 21 and material of the surface of the film 2 to be processed to react with each other. Further, since the metastable atoms 25 give off energy onto the surface of the film 2 to be processed immediately after they reach the surface of the film 2 to be processed, it becomes possible to cause the adhesion layer 21 and the film 2 to be processed to react efficiently to etch the film 2 to be processed.

After a prescribed time elapses from the beginning of the desorption process in Step 203, the RF power supplied to the coil 33 is stopped to extinguish the plasma 23, thereby finishing the desorption process. Thereafter, as shown in Part (d) of FIG. 3, the processing chamber 27 is evacuated to a degree of vacuum higher than the condition at which the plasma 23 is formed in as a short time as possible, so that the reaction products 6 desorbed from the surface of the wafer 1 are exhausted (Step 204 of FIG. 2). At this time, rare gases may be introduced into the processing chamber 27 to replace gas in the processing chamber 27 containing the reaction products 6.

In the present embodiment, letting the above-described plural processes from the adhesion in Step 201 via the desorption in Step 203 to the exhaust in Step 204 be one cycle, the number of implementations of the cycles is counted and stored so that the film 2 to be processed is etched to a desired thickness by repeatedly performing until the necessary number of times is reached. As shown in Step 205 of FIG. 2, it is judged after Step 204 whether the prescribed number of times of cycles is reached or not and, when it is judged that it is reached, the processing ends. When it is judged that it is not reached, it returns to Step 201 and the etching processing is performed again.

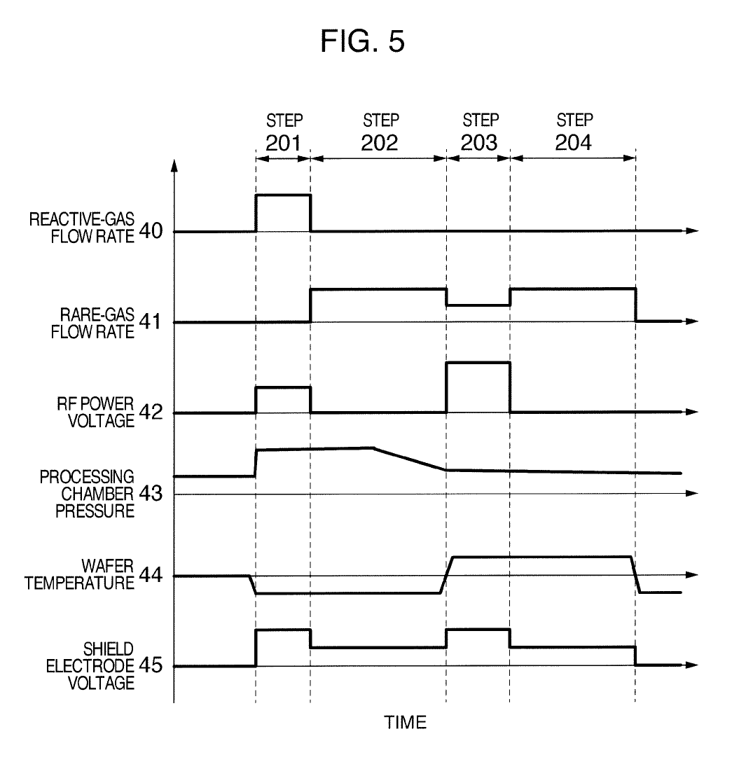

Next, referring to FIG. 5, the flow of operation at the time that the etching processing shown in FIG. 2 for removing the film 2 to be processed is performed with the above-described plasma processing apparatus according to the embodiment shown in FIG. 4 is described. FIG. 5 shows a timing chart exhibiting the flow of processing operation for removing the film to be processed in the plasma processing apparatus according to the embodiment shown in FIG. 4.

In the present embodiment, as parameters of conditions for the etching processing of the film 2 to be processed, there are enumerated, for example, a flow rate 40 of the reactive gas 16 for forming the adhesion layer 21, a flow rate 41 of the rare gas 31 for producing the VUV light 24 and the metastable atoms 25, voltage 42 of the RF power supply 32 for generating the rare-gas plasma 23, pressure 43 in the processing chamber 27, temperature 44 of the wafer 1, and voltage 45 supplied to the shield electrode 39 to suppress particles of the reactive gas 16 and the reaction products 6 from adhering onto the inner wall of the processing chamber 27. As shown in FIG. 5, values of the above parameters are adjusted in accordance with the respective steps in the flow chart of FIG. 2.

First, the wafer 1 is introduced into the processing chamber 27 and mounted on the wafer stage 28, and the processing chamber 27 is hermetically sealed. Thereafter, the inside of the processing chamber 27 is evacuated by operation of the vacuum pump 37 while adjusting a flow rate of exhaust by adjustment of an opening degree of the variable conductance valve 36.

In this state, adjustment of the temperature 44 of the wafer begins so that a value set to adsorb the reactive gas 16 is reached. The adjustment of the wafer temperature 44 started before the beginning of Step 201 may be made by adjusting the temperature of the wafer stage 28 or may be made by heating by radiation using a lamp (not shown) disposed in the upper part or the side part of the processing chamber 27. Alternatively, the surface of the wafer 1 may be irradiated with laser light.

Once a temperature sensor (not shown) detects that the temperature of the wafer 1 or the wafer stage 28 reaches a value within a prescribed range, the process of forming the adhesion layer 21 on the surface of the film 2 to be processed (Step 201) is performed. In this process, the processing chamber 27 is evacuated by operation of the vacuum pump 37 while the reactive gas 16 having reactivity with the film 2 to be processed is introduced into the processing chamber 27 by the gas supply measures so that the pressure 43 in the processing chamber 27 is adjusted by their balance to a prescribed value in a range suitable for the processing in Step 202.

Moreover, the RF power is supplied from the RF power supply 32 to the coil 33 at prescribed voltage 42, the reactive gas 16 introduced into the processing chamber 27 is excited to produce the plasma 22, and part of particles of the reactive gas is activated to produce the radicals 20. The radicals 20 having relatively high energies diffuse in the processing chamber 27 and reach the surface of the wafer 1 to form the adhesion layer 21 on the surface of the film 2 to be processed of the pattern 7.

At this time, in order to remove the charged particles such as ions generated from the plasma 22, the filter 34 may be disposed between the top surface of the wafer 1 and the room in which the plasma 22 is formed in the processing chamber 27. Further, in order to prevent particles of the reactive gas 16 from adhering onto the inner wall surface of the cylindrical processing chamber 27 or the like, the shield electrode 39 disposed on the outer periphery of the processing chamber 27 can be supplied with the voltage 45 from a DC power supply which is electrically connected to the shield electrode 39.

In the present embodiment, a gas of a mixture of a CHF₃ gas and an O₂ gas is used as the reactive gas for etching the Si₃N₄ film. The reactive gas is dissociated by the plasma to produce radicals such as CHFₓ, CFₓ, H, O, and F and uniformly forms the adhesion layer comprising elements of C, H, F and O on the material to be etched.

The kind of the reactive gas 16 to be used is properly selected in accordance with a pattern on which etching processing is performed. For example, when a SiO₂ film, a SiON film, or a Si₃N₄ film is etched, a combination of a gas containing fluorine and a gas containing oxygen or a combination of a gas containing hydrogen and a gas containing fluorine is used; a mixing ratio of gases is changed so that the mixing ratio is decided to increase a selection ratio with other film species.

As examples of a gas containing hydrogen, anhydrous HF, H₂, NH₃, CH₄, CH₃F, CH₂F₂, and the like are listed. Further, as examples of a gas containing fluorine, NF₃, CF₄, SF₆, CHF₃, CH₂F₂, CH₃F, anhydrous HF, and the like are listed. Moreover, inert gases such as Ar, He, Xe, and N₂ can be added to a gas containing hydrogen and a gas containing fluorine to dilute properly.

Furthermore, when a Si₃N₄ film is etched, a mixed gas containing nitrogen, oxygen, and fluorine is used in addition to a combination of a gas containing hydrogen and a gas containing fluorine as described above. As examples of a gas containing nitrogen, N₂, NO, N₂O, NO₂, N₂O₅, and the like are listed.

As examples of a gas containing oxygen, O₂, CO₂, H₂O, NO, N₂O, and the like are listed. Further, when a Si film is etched, a combination of a gas containing chlorine and a gas containing oxygen or a combination of hydrogen bromide (HBr), oxygen, and a gas containing nitrogen is conceivable. As examples of a gas containing chlorine, Cl₂, BCl₃, and the like are listed.

After a processing time set to form the adhesion layer 21 elapses from the beginning of the process in Step 201, supply of the reactive gas 16 by the valves 30 is stopped and power from the RF power supply to the coil 33 is stopped to reduce the voltage 42 to 0. Further, the DC voltage supplied to the shield electrode 39 is also reduced to a lower value.

Next, the inside of the processing chamber 27 is evacuated to a pressure value lower than that in Step 201 by operation of the vacuum pump 37 (Step 202). At this time, the opening degree of the variable conductance valve 36 is made larger than that in Step 202 so that the evacuation is made in as a short time as possible. Through this high-speed evacuation the reactive gas 16 remaining in the processing chamber 27 without adhering onto the wafer 1 are exhausted while the conductance of the evacuation path via the variable conductance valve 36 is maximized.

In this process, introduction of the rare gas 31 used to produce the VUV light 24 and the metastable atoms 25 in the subsequent Step 203 into the processing chamber 27 begins. By supplying the rare-gas to the processing chamber 27 at the flow rate 41 made larger than the flow rate of the rare gas 31 supplied in Step 203, the flow of the rare gas 31 in the processing chamber 27 can be utilized to be able to expel the remaining reactive gases 16 efficiently.

Further, by controlling the flow of the gases supplied from the gas supply measures, the remaining gases can be transported to the vacuum pump 37 and expelled efficiently. Using a disk-like shower plate or a doughnut-shaped introduction pipe, for example, as means for controlling the gas flow, the gas flow can be controlled from the center part of the wafer to the outer periphery.

After the high-speed evacuation of the processing chamber 27 is performed for a prescribed time, Step 203 for letting the adhesion layer 21 react with the film 2 to be processed and desorb from the surface of the wafer 1 is performed. First, the temperature of the wafer 1 is adjusted to be a wafer temperature 44 set in advance. In the present embodiment, since a set value T₃ of the wafer temperature 44 in the present Step 203 is different from a set value T₂ of the wafer temperature 44 in Step 202 only by a small amount, the adjustment of the wafer 1 to the set value T₃ can be made in a short time.

Next, the flow rate 41 of the rare gas 31 for forming the rare-gas plasma 23 which produces the VUV light 24 and the metastable atoms 25 is adjusted to a value suitable for formation of the rare-gas plasma 23. The introduced rare gas 31 is excited by the electric field formed by the RF power supplied from the RF power supply 32 to the coil 33 at the voltage 42, so that the rare-gas plasma 23 is formed in the processing chamber 27. The VUV light 24 and the metastable atoms 25 are produced from the rare-gas plasma 23. In the present embodiment, the value of the voltage 42 of the RF power is set to be greater than that in Step 201.

The VUV light 24 is radiated to the surface of the wafer 1 and the metastable atoms 25 diffuse to reach the surface of the wafer 1, so that energy for reaction and desorption is given to the adhesion layer 21. Particularly, since the metastable atoms 25 have no directivity, they can reach even the bottom 12 of the pattern 7 having a high aspect ratio and give energy required for reaction and desorption thereto.

Furthermore, the VUV light 24 reaches the pattern 7 on the surface of the wafer 1 with no directivity, so that energy required for reaction and desorption can be given onto the surface of the adhesion layer 21 of the pattern 7 efficiently. For example, when Ar is used as the rare gas, the VUV light of the wavelengths of 104.8 nm, 106.6 nm, and the like can be radiated.

When the VUV light 24 is converted into energies, it is 11.8 eV and 11.6 eV. When Ar is used as the rare gas, the metastable atoms 25 having the excitation energies of 11.7 eV and 11.5 eV can be produced simultaneously with the generation of the VUV light 24.

When Ne is used as the rare gas, the VUV light 24 of the wavelengths of 73.6 nm, 74.4 nm, and the like can be radiated. When the VUV light is converted into energies, it is 16.9 eV and 16.7 eV. When Ne is used as the rare gas, the metastable atoms 25 having the excitation energies of 16.6 eV and 16.7 eV can be produced simultaneously with the generation of the VUV light 24.

Further, when He is used as the rare gas, the VUV light 24 of the wavelengths of 58.4 nm and the like can be radiated. When the VUV light 24 is converted into energies, it is 21.2 eV. When He is used as the rare gas, the metastable atoms 25 having the excitation energies of 19.8 eV and 20.6 eV can be produced simultaneously with the generation of the VUV light 24.

When Xe is used as the rare gas, the VUV light 24 of the wavelengths of 146.9 nm and the like can be radiated. When the VUV light is converted into energies, it is 8.4 eV. When Xe is used as the rare gas, the metastable atoms 25 having the excitation energy of 8.5 eV can be produced simultaneously with the generation of the VUV light 24. When such VUV light 24 is used, the light energy larger than or equal to bonding energies can be given, which is required for generation of the reaction products 6.

Moreover, the bonding between the reaction products and the surface of the wafer 1 can be cut off and the reaction products 6 can be desorbed from the surface efficiently. For example, when Si₃N₄ is etched, by casting the VUV light 24 and the metastable atoms 25 having the energy at least larger than the bonding energy of 4.8 eV of Si and N, the reaction products 6 can be generated and desorbed efficiently.

In Step 203, the voltage 45 on the shield electrode 39 is set to a prescribed value in the same manner as in Step 201 so that the reaction products 6 can be suppressed from adhering onto the inner wall of the processing chamber 27. In the present embodiment, the process in Step 203 is terminated by stopping supply of the RF power to the coil 33 and stopping formation of the rare-gas plasma 23 after the rare-gas plasma 23 is formed continuously for a predetermined time.

After the reaction products 6 are desorbed from the surface of the wafer 1 in Step 203, the voltage 42 of the RF power supply supplied to generate the rare-gas plasma 23 is stopped. Further, the voltage on the shield electrode 39 is also set to the same value as in Step 202. In this state, the opening degree of the variable conductance valve 36 is set to maximize the conductance thereof so that the reaction products 6 and the rare gas 31 remaining in the processing chamber 27 are expelled at a high speed by operation of the vacuum pump 37 (Step 204).

At this time, the flow rate 41 of the rare gas 31 supplied to the processing chamber 27 is set to be higher than that in Step 203 and the flow of the rare gas 31 in the processing chamber 27 is utilized to expel the reaction products 6 and the rare gas supplied in Step 203 efficiently. By controlling the flow of the gas supplied from the gas supply measures the reaction products 6 can be efficiently transported to the vacuum pump 37 and expelled.

Thereafter, judgment as to whether the next cycle is required to be performed or not is made (Step 205) and, when it is judged that implementation of the next cycle is required, adjustment to the wafer temperature 44 set to cause the etchant such as the reactive gas 16 to 3U adhere in Step 201 of the next cycle is started. Since a net value T₁ of the wafer temperature in Step 201 in the present embodiment is different from the set value T₃ of the wafer temperature in Step 203 only by a small amount, the time required for temperature adjustment to achieve is 1 minute or less.

By repeating the above-described cycle the number of times recognized to be necessary, complicated patterns can be etched with high accuracy. Further, in Steps 202 and 204, the exhaust time is shortened than in the prior art, so that the throughput is improved.

In the present embodiment, even when patterns 7 having holes and grooves of high aspect ratios with high density as shown in FIG. 1B are machined, the metastable atoms 25 generated from the rare-gas plasma 23 can reach the lower part 11 of the pattern side wall and the bottom 12 of the pattern, and the energy for generating and desorbing the reaction products 6 is given thereto, so that the etching can be made with high accuracy. Moreover, even when patterns 7 of two or more kinds having different pattern widths and aspect ratios (densities) as shown in FIGS. 1A and 1B are formed on the same wafer, the metastable atoms 25 can reach the lower part 11 of the pattern side wall and the bottom 12 of the pattern, and scattering in the dimensions of the patterns 7 in the in-plane direction of the wafer 1 as a result of the etching processing can be reduced.

Furthermore, even when material to be etched is subjected to isotropic etching in a pattern having its upper part larger than its bottom as shown in FIG. 1C, since the metastable atoms 25 can reach even shaded parts 13, the etching can be made with high accuracy. Moreover, the above-described high-accurate and damage-free etching can be realized with higher throughput than in a conventional thermal desorption method.

Incidentally, the present invention is not limited to the structure of the above-described embodiment, which may be replaced by substantially the same structure, the structure having the same operational effects, or the structure which can attain the same object as the structure of the embodiment.

### Variation

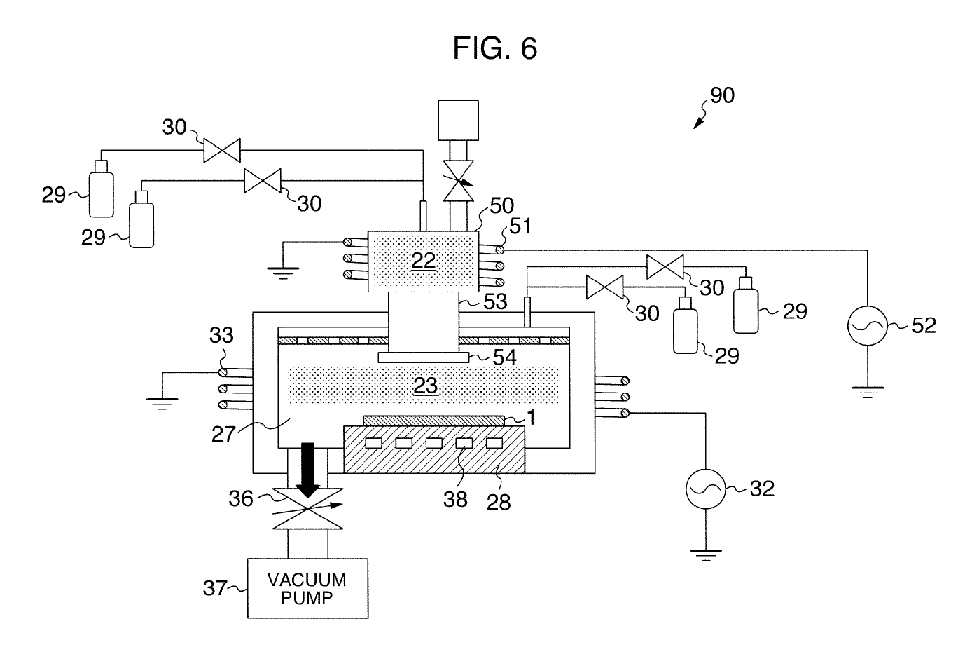

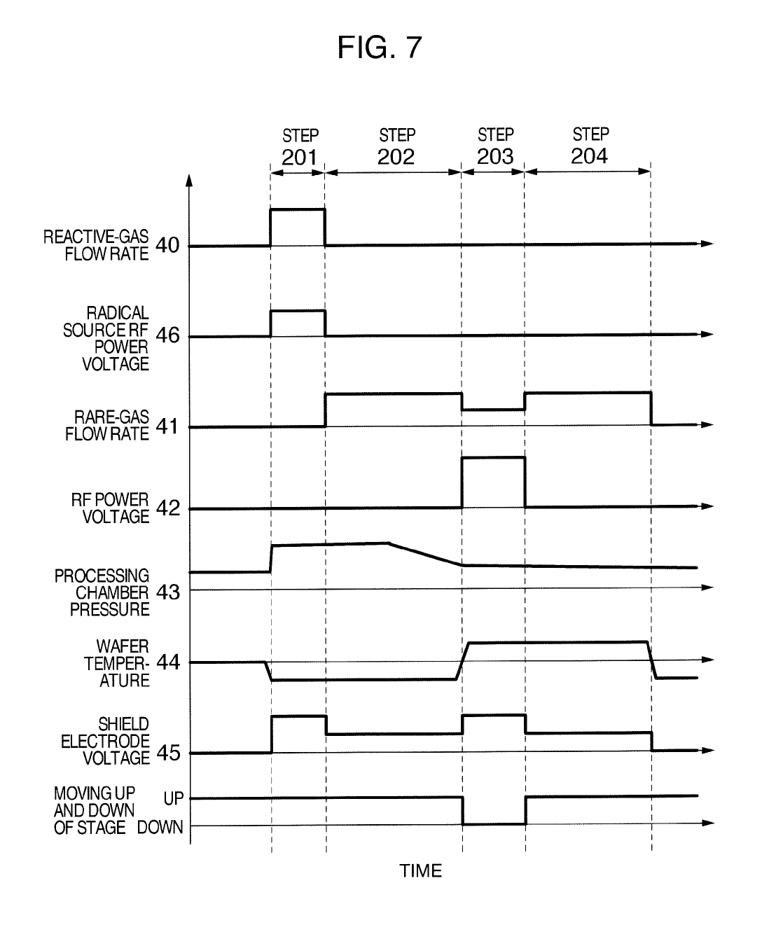

A variation of the embodiment of the present invention is described with reference to FIGS. 6 and 7. FIG. 6 shows a longitudinal sectional view schematically illustrating the configuration of the variation of the plasma processing apparatus according to the embodiment shown in FIG. 4. The processes and the conditions of the etching processing in the present variation are the same as those in FIGS. 2 and 3.

An plasma processing apparatus 90 according to the present variation has the same structure as that of the plasma processing apparatus 26 of FIG. 4 in that it includes the processing chamber 27 disposed in the vacuum container, the wafer stage 28 disposed therein, the coil 33 wound on the outer peripheral side of the vacuum container and electrically connected to the RF power supply 32, the exhaust device having the variable conductance valve 36 and the vacuum pump 37, and the gas supply measures for supplying gases into the processing chamber 27 through the gas supply paths having the gas cylinders 29 and the valves 30 disposed thereon. The plasma processing apparatus 90 of the present variation, on the other hand, includes a radical source 50, which is a vacuum container to provide etchant such as the radicals 20 and the reactive gases 16 to the processing chamber 27, disposed above the processing chamber 27 in the vacuum container.

The radical source 50 of the present variation is connected to the gas supply measures including the gas supply paths having the gas cylinders 29 and the valves 30 thereon, and the reactive gases 16 from the gas cylinders 29 are introduced into a reaction chamber in the radical source 50 through the gas supply paths with their flow rates adjusted by the valves 30.

The radical source 50 includes a coil 51 which is wound on the outer peripheral side of the container, disposed with a gap, and electrically connected to a RF power supply 52. The reactive gases 16 introduced into the radical source 50 are excited by an electric field formed inside as RF power is supplied from the RF power supply 52 to the coil 51 so that the plasma 22 is formed in the radical source 50 and the radicals 20 are produced. The produced radicals 20 are supplied to room for processing in the processing chamber 27 through a gas introduction pipe 53 which is coupled to the upper surface of the vacuum container constituting the processing chamber 27 to communicate the radical source 50 and the processing chamber 27 with each other.

Similar to Step 201 of the embodiment of FIG. 2, the radicals 20 supplied to the processing chamber 27 reach the surface of the wafer 1 and form the adhesion layer 21. Further, the reactive gases 16 supplied to the radical source 50 from the gas supply measures may be caused to adhere onto the film 2 to be processed just as they are without being excited in the radical source 50 and producing the plasma 22. Moreover, in the present variation, a shutter 54 is disposed between the radical source 50 and the processing chamber 27 so that communication therebetween can be hermetically closed immediately after Step 202 of FIG. 2 is ended.

Further, the processing chamber 27 is provided with gas supply measures including gas cylinders 29 and valves 30 for introducing the rare gases 31 and, after the rare gases 31 supplied from the gas cylinders 29 are introduced through the valves 30 into the room which is between the shower plate constituting the ceiling surface of the processing chamber 27 and the upper part of the vacuum container and disposed in a form of a ring around the gas introduction pipe 53, and diffused, they are introduced via through-holes communicating between the room and the processing chamber 27 into the processing chamber 27 uniformly in the circumferential direction. The introduced rare gases 31 are excited by RF power supplied from the RF power supply 32 to the coil 33 to form the plasma 23 in the processing chamber 27, so that the metastable atoms 25 and the VUV light 24 are generated.

The metastable atoms 25 diffuse in the processing chamber 27 and reach the surface of the wafer 1. Since the metastable atoms 25 have no directivity, they can reach even the bottom 12 of a pattern having a high aspect ratio of FIG. 1B and provide reaction energy to the adhesion layer 21 and the film 2 to be processed. Part of the VUV light 24 generated from the rare-gas plasma 23 can reach the bottom 12 of the pattern and provide reaction energy thereto.

In this example, the frequency of the RF power of the RF power supply 32 is properly selected from a range of 400 kHz to 40 MHz; in this example 13.56 MHz is used.

Further, in this example, in order to suppress charged particles such as ions generated from the rare-gas plasma 23 from reaching the wafer 1, a filter may be disposed over the wafer 1. The amount of exhaust is balanced by the opening degree of the variable conductance valve 36 connected to the processing chamber 27 and operation of the vacuum pump 37 while the rare gases 31, or the radicals 20 or the reactive gases are supplied at a prescribed flow rate from the gas supply measures coupled to the vacuum container or from the gas introduction pipe 53, respectively, to maintain the pressure in the processing chamber to a value in a range suitable for processing.

A structure for heating or cooling can also be disposed in the wafer stage 28. In the present variation, a thermoelectric module which generates heat as electric power is supplied thereto is disposed together with the coolant flow passage 38 inside the metallic member in the wafer stage 28. By operation of the thermoelectric module and the coolant flow passage 38, a construction is adopted with which the temperature of the wafer 1 can be controlled to be 0 to 100° C., for example. Further, the wafer stage 28 may be provided with an up-and-down mechanism.

In this example, a construction may be adopted in which, when the reactive gases 16 and the radicals 16 are caused to adhere onto the surface of the wafer 1 to form the adhesion layer 21 in Step 201 of the etching processing process shown in FIG. 2, the position of the top surface of the wafer stage 28 in the height direction is heightened so that its distance from the shower plate is made small and, when the rare-gas plasma 23 is used to let the adhesion layer 21 react with the film 2 to be processed and desorb in Step 203, the position of the wafer stage 28 in the height direction is lowered so that enough room to generate the rare-gas plasma 23 can be formed. By setting the height position of the wafer stage 28 near to the radical source 50, the time required for adhesion of the radicals 20 in Step 201 and the time of expelling the remaining radicals 20 and the remaining reactive gases 16 in Step 203 can be shortened, thereby enabling suppression of the radicals 20 and the reactive gases 16 from adhering onto the inner wall of the processing chamber 27 and the accuracy of etching can be improved.

When the voltage of the RF power is applied to the coil 33 in Step 203, the height position of the top surface of the wafer stage 28 is lowered before the rare-gas plasma 23 is generated. Most of the wall in the processing chamber 27 in the area where the plasma 23 is generated does not have the radicals 20 adhering thereon and, accordingly, influences of the remaining radicals and the remaining gases can be mitigated.

Next, referring to FIG. 7, description is made to the flow of operation when the plasma processing apparatus according to the embodiment shown in FIG. 6 performs the etching processing shown in FIG. 2 to remove the film 2 to be processed. FIG. 7 shows a timing chart exhibiting the flow of processing operation for removing the film to be processed in the plasma processing apparatus according to the embodiment shown in FIG. 6.

In the present variation, as parameters of conditions for the etching processing of the film 2 to be processed, there are enumerated, for example, the flow rate 40 of the reactive gas 16 for forming the adhesion layer 21, the flow rate 41 of the rare gas 31 for producing the VUV light 24 and the metastable atoms 25, the voltage 42 of the RF power supply 32 for generating the rare-gas plasma 23, the pressure 43 in the processing chamber 27, the temperature 44 of the wafer 1, and the voltage 45 supplied to the shield electrode 39 to suppress particles of the reactive gas 16 and the reaction products 6 from adhering onto the inner wall of the processing chamber 27.

As shown in FIG. 7, values of the above parameters are adjusted in accordance with the respective steps in the flow chart of FIG. 2. Further, the position of the top surface of the water stage 28 in the height direction is changed properly as needed.

First, the wafer 1 is introduced into the processing chamber 27 and mounted on the wafer stage 28, and the processing chamber 27 is hermetically sealed Thereafter, the inside of the processing chamber 27 is evacuated by operation of the vacuum pump 37 while adjusting the flow rate of exhaust by adjustment of the opening degree of the variable conductance valve 36.

In this state, adjustment of the temperature 44 of the wafer begins so that the value set to adsorb the reactive gas 16 is reached. The adjustment of the wafer temperature 44 started before the beginning of Step 201 may be made by adjusting the temperature of the wafer stage 28 or may be made by heating by radiation using a lamp (not shown) disposed in the upper part or the side part of the processing chamber 27. Alternatively, the surface of the wafer 1 may be irradiated with laser light.

The adjustment of the wafer temperature is made by the wafer stage 28 in the present embodiment; the adjustment, however, may be made by heating using a lamp or by irradiating the surface of the wafer 1 with laser light. Further, the position of the top surface of the wafer stage 28 may be raised by the up-and-down mechanism of the position in the height direction of the wafer stage 28 so that the distance between the radical source 50 and the wafer 1 may be made shorter.

Next, when the radicals 20 are supplied into the processing chamber 27 as the reactive gas 16 in Step 201, operation of the vacuum pump 37 or the opening degree of the variable conductance valve 36 is adjusted to regulate the pressure in the radical source 50 to a value in a prescribed range while the gas 16 having reactivity with the film 2 to be processed is introduced into the radical source 50 by the gas supply measures. The reactive gas 16 introduced into the radical source 50 is excited by the RF power supplied from the RF power supply 52 to the coil 51 disposed to be wound around the outer periphery of the radical source 50, so that the plasma 22 is formed.

The plasma 22 generates radicals 20 from particles of the reactive gas or the reaction products therein. The generated radicals 20 are supplied into the processing chamber 27 through the gas introduction pipe 53 having an opening in the center part of the ceiling surface of the processing chamber 27 and diffuse in the processing chamber 27 to reach the surface of the wafer 1, no that the adhesion layer 21 is formed on the surface of the pattern 7.

The shutter 54 is disposed at an end part of the gas introduction pipe 53 on the side of the processing chamber 27 so that it is configured that a communication between the inside of the processing chamber 27 and the inside of the radical source 50 through the opening can be opened and closed. By opening the shutter 54 at the beginning of Step 201 and closing the shutter 54 at the end of Step 201, supply of the radicals can be started and stopped with high accuracy. Further, a disk-like shower plate or a doughnut-shaped introduction pipe, for example, can be used as means for controlling the gas flow and the etchant such as the reactive gas and the radicals 20 can be caused to adhere more uniformly in the in-plane direction of the wafer 1.

Moreover, in order to suppress the reactive gas 16 from adhering onto the inner wall surface of the processing chamber 27, a shield electrode (not shown) disposed on the outer periphery of the processing chamber 27 can be supplied with voltage. By raising the position of the wafer stage to reduce the distance between the radical source 50 and the wafer 1 in Step 201, the time required for adhesion of the radicals 20 can be reduced and the time required for expelling the remaining radicals 20 and the remaining reactive gas 16 in Step 203 can be reduced.

Further, in Step 201, adhesion of the radicals 20 onto the wall in the processing chamber 27 can be prevented and the etching accuracy can be improved. At this time, the kind of the reactive gas 16 used is properly selected in accordance with a pattern subjected to the etching processing as described in the previous embodiment.

When it is detected that the time set to form the adhesion layer 21 has elapsed after the beginning of Step 201, supply of the reactive gas 16 by the valves 30 is stopped and, at the same time as the shutter 54 of the gas introduction pipe 53 is closed, supply of electric power of the RF power supply for generating the plasma 22 is stopped. The remaining of the reactive gas 16 residing in the processing chamber 27 without forming the adhesion layer 21 on the wafer 1 is expelled out of the processing chamber 27 at a high speed by operation of the vacuum pump 37 with the opening degree of the variable conductance valve 36 set to position so that the conductance is maximized (Step 202).

At this time, introduction of the rare gas 31 into the processing chamber 27 for generating the VUV light 24 and the metastable atoms 25 is started in Step 203. The flow rate 41 of the rare gas 31 is set to be larger than the flow rate in Step 203 so that the flow of the rare gas in the processing chamber 27 is utilized to expel the reactive gas 16 efficiently.

By controlling the flow of the gas supplied from the gas supply measures, the etchant such as the reactive gas 16 remaining in the processing chamber 27 can be transported to the vacuum pump 37 and exhausted efficiently. Using a disk-like shower plate or a doughnut-shaped introduction pipe disposed in the processing chamber 27, for example, as means for controlling the gas flow, the gas flow going from the center part of the wafer 1 toward the outer periphery thereof may be formed.

When the position of the top surface of the wafer stage 28 in the height direction is made closer to the radical source 50 in Step 201, the top surface of the wafer stage 28 is lowered and moved to a position lower than the region where the rare-gas plasma 23 is produced in Step 203. Next, the rare-gas plasma 23 is formed in the processing chamber 27 and letting the adhesion layer 21 and the material of the surface of the film 2 to be processed react with each other to perform Step 203 which is the process for the reaction products 6 to vaporize and to be desorbed.

In this Step, first, the temperature of the wafer 1 or the wafer stage 28 is adjusted to reach the wafer temperature 44 of a value in a range set in advance. Next, the opening degree of the valve 30 is adjusted so that the flow rate 41 of the rare gas 31 takes a value in a set range.

The pressure in the processing chamber 27 is adjusted to a value in a range suitable for processing by letting the flow rate of the rare gas 31 introduced into the processing chamber 27 and the opening degree of the variable conductance valve 36 and the operation of the vacuum pump 37 balancing out, and the RF power from the RF power supply 32 is applied to the coil 33 at the voltage 42. The rare gas 31 supplied into the processing chamber 27 is excited by the electric field generated from the coil 33 to form the rare-gas plasma 23, and the VUV light 24 and the metastable atoms 25 are produced from the rare-gas plasma 23.

The pattern 7 on the surface of the wafer 1 and the adhesion layer 21 formed on the surface are irradiated with the VUV light 24, the metastable atoms 25 diffuse in the processing chamber 27 to reach the surface of the pattern 7 on the wafer 1, and energy for generation and desorption of the reaction products 6 is given to the adhesion layer 21 and the film 2 to be processed. Particularly, since the metastable atoms 25 have no directivity, they can reach even the bottom 12 of a pattern 7 of a high aspect ratio and give the energy required for reaction and desorption thereto. Further, even the bottom 12 of the pattern 7 on the surface of the wafer 1 can be irradiated with the VUV light 24 with no directivity and can be given the energy required for reaction and desorption efficiently.

After it is judged that a prescribed time elapses from formation of the rare-gas plasma 23 in Step 203 so that the reaction products 6 are desorbed from the surface of the wafer 1, application of the voltage 42 from the RF power supply 32 is stopped and the rare-gas plasma 23 is extinguished. Since the operation of the vacuum pump 37 continues regardless of formation and extinguishment of plasma, even after extinguishment of the rare-gas plasma 23, the reaction products 6 and the rare gas 31 remaining in the processing chamber 27 are exhausted from the processing chamber 27 at a high speed while the conductance of the variable conductance valve 36 is maximized (Step 204).

At this time, the flow rate 41 of the rare gas 31 is made larger than the flow rate in Step 203 and the flow of the rare gas 31 is utilized to expel the reaction products 6 efficiently. Similarly, by controlling the gas flow supplied from the gas supply measures, the reaction products 6 are transported to the vacuum pump 37 and expelled efficiently. Further, the height position of the top surface of the wafer stage 28 is moved up to a closer position to the shower plate, thereby improving the efficiency of discharge of the remaining reaction products 6.

Thereafter, judgment as to whether the next cycle is required to be performed or not is made (Step 205) and, when it is judged that implementation of the next cycle is required, adjustment to the wafer temperature 44 set to cause the etchant such as the reactive gas 16 to adhere in Step 201 of the next cycle is started. Since the set value T₁ of the wafer temperature in Step 201 in the present embodiment is different from the set value T₃ of the wafer temperature in Step 203 only by a small amount, the time required for temperature adjustment to be achieved is 1 minute or less.

By repeating the above-described cycle the number of times recognized to be necessary, complicated patterns can be etched with high accuracy. Thus, the yield of the etching processing is improved. Further, in Steps 202 and 204, the exhaust time is shortened than in the prior art, so that the throughput is improved.

Incidentally, the present invention is not limited to the above embodiment and may be replaced by substantially the same structure, the structure having the same operational effects, or the structure which can attain the same object as the structure shown in the embodiment.

1. A plasma processing method comprising:
a first step of disposing a wafer to be processed in a processing chamber depressurized in a vacuum container and introducing into the processing chamber a gas having reactivity with a film to be processed disposed in advance on a top surface of the wafer to form an adhesion layer on the film;
a second step of expelling a part of the gas having reactivity which remains in the processing chamber while supply of the gas having reactivity is stopped;
a third step of introducing a rare gas into the processing chamber to form a plasma in the processing chamber and desorbing reaction products of the adhesion layer and the film to be processed from the wafer using particles in the plasma and vacuum ultraviolet light generated from the plasma; and
a fourth step of expelling the reaction products from the processing chamber while the plasma is not formed.

2. The plasma processing method according to claim 1, wherein the first step to form the adhesion layer is performed by letting radicals formed from the gas having reactivity adhere onto the film to be processed.

3. The plasma processing method according to claim 2, wherein the first step to form the adhesion layer is performed by letting the radicals formed in a second chamber other than the processing chamber are supplied into the processing chamber adhere onto the film to be processed.

4. The plasma processing method according to claim 1,
wherein the first step is performed while the wafer is adjusted to have a first temperature suitable for the first step,
wherein the third step is performed while the wafer is adjusted to have a second temperature suitable for the third step.

5. The plasma processing method according to claim 1, wherein at least either of the second and fourth steps of expelling is performed while supplying a rare gas into the processing chamber.

6. The plasma processing method according to claim 5, wherein a flow rate of the rare gas supplied in at least either of the second and fourth steps is different from a flow rate of the rare gas introduced in the third step.

7. The plasma processing method according to claim 1, wherein at least either of the second and fourth steps is performed with a height of a top surface of a sample stage disposed in the processing chamber and on which the wafer is mounted is made higher than a height of the top surface of the sample stage in either of the first and third steps.
